(19) United States
(12) Patent Application Publication
(10) Pub. No.: US 2015/0214369 A1
(43) Pub. Date: Jul. 30, 2015

(54) METHODS OF FORMING EPITAXIAL SEMICONDUCTOR MATERIAL ON SOURCE/DRAIN REGIONS OF A FINFET SEMICONDUCTOR DEVICE AND THE RESULTING DEVICES

(71) Applicant: GLOBALFOUNDRIES Inc., Grand Cayman, KY (US)

(72) Inventors: Jody A. Fronheiser, Delmar, NY (US); Bharat V. Krishnan, Mechanicville, NY (US); Murat Kerem Akarvardar, Saratoga Springs, NY (US); Steven Bentley, Watervliet, NY (US); Ajey Poovannummoottil Jacob, Watervliet, NY (US); Jinping Liu, Ballston Lake, NY (US)

(73) Assignee: GLOBALFOUNDRIES Inc., Grand Cayman, KY (US)

(21) Appl. No.: 14/164,934

(22) Filed: Jan. 27, 2014

(51) Int. Cl. H01L 29/78; H01L 29/16; H01L 29/66; H01L 29/167; H01L 29/26; H01L 29/04; H01L 29/161

(52) U.S. Cl. CPC H01L 29/7851; H01L 29/045; H01L 29/16; H01L 29/161; H01L 29/167; H01L 29/26; H01L 29/66795; H01L 29/7848

(57) ABSTRACT

One illustrative device disclosed herein includes a fin defined in a semiconductor substrate having a crystalline structure, wherein at least a sidewall of the fin is positioned substantially in a <100> crystallographic direction of the substrate, a gate structure positioned around the fin, an outermost sidewall spacer positioned adjacent opposite sides of the gate structure, and an epi semiconductor material formed around portions of the fin positioned laterally outside of the outermost sidewall spacers in the source/drain regions of the device, wherein the epi semiconductor material has a substantially uniform thickness along the sidewalls of the fin.

### BACKGROUND OF THE INVENTION

1. Field of the Invention

Generally, the present disclosure relates to the manufacture of FET semiconductor devices, and, more specifically, to various methods of forming epitaxial semiconductor material on source/drain regions of a FinFET semiconductor device and the resulting device structures.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein so-called metal oxide field effect transistors (MOSFETs or FETs) represent one important type of circuit element that substantially determines performance of the integrated circuits. A conventional FET is a planar device that typically includes a source region, a drain region, a channel region that is positioned between the source region and the drain region, and a gate electrode positioned above the channel region. Current flow through the FET is controlled by controlling the voltage applied to the gate electrode. For example, for an NMOS device, if there is no voltage applied to the gate electrode, then there is no current flow through the NMOS device (ignoring undesirable leakage currents, which are relatively small). However, when an appropriate positive voltage is applied to the gate electrode, the channel region of the NMOS device becomes conductive, and electrical current is permitted to flow between the source region and the drain region through the conductive channel region.

To improve the operating speed of FETs, and to increase the density of FETs on an integrated circuit device, device designers have greatly reduced the physical size of FETs over the past decades. More specifically, the channel length of FETs has been significantly decreased, which has resulted in improving the switching speed and in lowering operation currents and voltages of FETs. However, decreasing the channel length of a FET also decreases the distance between the source region and the drain region. In some cases, this decrease in the separation between the source and the drain makes it difficult to efficiently inhibit the electrical potential of the source region and the channel from being adversely affected by the electrical potential of the drain. This is sometimes referred to as a so-called short channel effect, wherein the characteristic of the FET as an active switch is degraded.

In contrast to a FET, which has a planar structure, a so-called FinFET device has a three-dimensional (3D) structure. FIG. 1A is a perspective view of an illustrative prior art FinFET semiconductor device 10 that is formed above a semiconductor substrate 12 that will be referenced so as to explain, at a very high level, some basic features of a FinFET device 10. In this example, the FinFET device 10 includes three illustrative fins 14, a gate structure 16, sidewall spacers 18 and a gate cap layer 20. The gate structure 16 is typically comprised of a layer of gate insulating material (not separately shown), e.g., a layer of high-k insulating material or silicon dioxide, and one or more conductive material layers (e.g., metal and/or polysilicon) that serve as the gate electrode for the device 10. The fins 14 have a three-dimensional configuration: a height 14H, a width 14W and a long-axis or axial length 14L. The axial length 14L corresponds to the direction of current travel in the device 10 when it is operational. The dashed line 14C depicts the long-axis or centerline of the fins 14. The portions of the fins 14 covered by the gate structure 16 are the channel regions of the FinFET device 10. In a conventional process flow, the portions of the fins 14 that are positioned outside of the spacers 18, i.e., in the source/drain regions of the device 10, may be increased in size or even merged together (a situation not shown in FIG. 1A) by performing one or more epitaxial growth processes. The process of increasing the size of or merging the fins 14 in the source/drain regions of the device 10 is performed to reduce the resistance of source/drain regions and/or make it easier to establish electrical contact to the source/drain regions. Even if an epi “merge” process is not performed, an epi growth process will typically be performed on the fins 14 to increase their physical size.

In the FinFET device 10, the gate structure 16 may enclose both sides and the upper surface of all or a portion of the fins 14 to form a tri-gate structure so as to use a channel having a three-dimensional structure instead of a planar structure. In some cases, an insulating cap layer (not shown), e.g., silicon nitride, is positioned at the top of the fins 14, and the FinFET device 10 only has a dual-gate structure (sidewalls only). Unlike a planar FET, in a FinFET device, a channel is formed perpendicular to a surface of the semiconducting substrate so as to reduce the physical size of the semiconductor device. Also, in a FinFET, the junction capacitance at the drain region of the device is greatly reduced, which tends to significantly reduce short channel effects. When an appropriate voltage is applied to the gate electrode of a FinFET device, the surfaces (and the inner portion near the surface) of the fins 14, i.e., the vertically oriented sidewalls and the top upper surface of the fin, form a surface inversion layer or a volume inversion layer that contributes to current conduction. In a FinFET device, the “channel-width” is estimated to be about two times (2×) the vertical fin-height of the fin 14 plus the width of the top surface of the fin 14, i.e., the fin width. Multiple fins can be formed in the same foot-print as that of a planar transistor device. Accordingly, for a given plot space (or foot-print), FinFET devices tend to be able to generate significantly higher drive current density than planar transistor devices. Additionally, the leakage current of FinFET devices after the device is turned “OFF” is significantly reduced as compared to the leakage current of planar FETs, due to the superior gate electrostatic control of the “fin” channel on FinFET devices. In short, the 3D structure of a FinFET device is a superior MOSFET structure as compared to that of a planar FET, especially in the 20 nm CMOS technology node and beyond. The gate structures 16 for such FinFET devices 10 may be manufactured using so-called “gate-first” or “replacement gate” (gate-last) manufacturing techniques. View “X-X” in FIG. 1A depicts the locations where various cross-sectional views of the devices disclosed herein may be taken in the drawings discussed below, i.e., through what will become a source/drain region for the device in a direction that is perpendicular to the long axis 14L of the fins 14 (or stated another way, in a direction that is parallel to the gate width direction of the device 10).

FIG. 1B depicts an illustrative prior art example of how the fins 14 of a FinFET device 10 may be oriented relative to the crystallographic orientation of the substrate 12. FIG. 1B depicts an illustrative prior art substrate 10 having a (100) crystalline structure, wherein the use of “( )” denotes a specific plane. Such (100) substrates are well known in the art and are generally commercially available from a number of manufacturers. As is well known to those skilled in the art, the substrate 12 is manufactured in such a manner that the crystalline planes within the substrate 12 are arranged in a certain ordered arrangement.

One process flow that is typically performed to form the FinFET device 10 depicted in FIG. 1B involves forming a plurality of trenches 19 in the substrate 12 to define the areas where STI regions will be formed and to define the initial structure of the fins 14, and these trenches may be formed in the substrate 12 during the same process operation for processing simplicity. In some cases, the trenches 19 are desirably designed with the same pitch (for better resolution during lithography) and they are formed to the same depth and width (for processing simplicity and various functional requirements), wherein the depth of the trenches 19 is sufficient for the needed fin height and deep enough to allow formation of an effective STI region. After the trenches 19 are formed, a layer of insulating material 22, such as silicon dioxide, is formed so as to overfill the trenches 19. Thereafter, a chemical mechanical polishing (CMP) process is performed to planarize the upper surface of the insulating material 22 with the top of the fins 14 (or the top of a patterned hard mask). Thereafter, an etch-back process is performed to recess the layer of insulating material 22 between the fins 14 and thereby expose the upper portions of the fins 14, which corresponds to the final fin height of the fins 14.

FIG. 1C is a plan view of the device with various cross-sectional views of the device as well. As indicated in FIGS. 1B-1C, for a (100) silicon substrate 12, in traditional manufacturing techniques, the substrate 12 is oriented during manufacturing of the device 10 such that the sidewalls 14S of the fins 14 are oriented in the [110] direction while the long axis of the fins 14, i.e., the current transport direction when the device 10 is in operation, is also oriented in the [110] direction, and the upper surface 14U of the fins 14 is facing in the direction. More specifically, FIG. 1C depicts an illustrative prior art substrate 12 having a (100) crystalline structure, wherein the use of “( )” denotes a specific plane. Such (100) substrates 12 are well known in the art and are generally commercially available from a number of manufacturers. The substrate 12 includes an illustrative notch 11 that, in the depicted example, indicates the crystallographic direction in the “Y” or vertical direction 13 (in a plan view), i.e., the <110> crystallographic direction. As is well known to those skilled in the art, the substrate 12 is manufactured in such a manner that the crystalline planes within the substrate 12 are arranged in a certain ordered arrangement. For example, FIG. 1C contains a plan view of such an illustrative substrate 12 with a surface normal “Z” in the (001) crystalline plane. As depicted therein, the (100) substrate 12 has a <110> crystallographic direction in the “Y” or vertical direction 13 (in a plan view) and a <110> crystallographic direction in the “X” or horizontal direction 15 (in a plan view). As used herein, the “< >” designation reflects an identification of a family of equivalent directions. The (100) substrate 12 also has a <001> crystallographic direction 16 in the “Z” direction i.e., in the direction into and out of the plan view drawing in FIG. 1C. The plan view in FIG. 1C also reflects how illustrative fins 14 of the FinFET device 10 are typically oriented relative to various crystallographic structures of the (100) substrate 12. In general, the long axis 14L of the fins 14 and the sidewall surfaces 14S of the fins 14 are typically oriented in the <110> direction of the crystalline structure of the substrate 12. Also depicted in FIG. 1C is a cross-sectional view and a top view of an illustrative fin structure 14 showing the crystalline orientation of various aspects of the fin 14 that is formed in the (100) substrate 12. As can be seen in these views, both the long axis 14L of the fin 14 and the sidewalls 14S of the fin are positioned in the <110> crystallographic direction of the crystalline structure of the substrate 12. Of course, in the case where the fins 14 have a tapered cross-sectional configuration as opposed to the idealized rectangular cross-sectional configuration shown in FIG. 1B, the sidewalls 14S of such tapered fins may be positioned slightly out of the <110> direction due to the tapered shape of the tapered fins.

After the fins 14, the gate structure 16, the spacers 18 and the cap layer 20 are formed, epitaxial semiconductor material, e.g., silicon, silicon/germanium, is typically deposited/grown on the exposed portions of the fins 14 that are not covered by the gate structure 16, the spacers 18 and the cap layer 20. Due to the crystallographic orientation substrate 12 (100), and the orientation of the fins 14 formed on such a substrate, the additional epi semiconductor material 24 will form so as to exhibit a general diamond-shaped configuration depicted in FIG. 1D. The approximate outline of the original fins 14 is depicted by the dashed line 14X in FIG. 1D. The formation of the diamond-shaped epi semiconductor material 24 is purely a result of the kinetics of the epi deposition process and the crystallographic orientation of the fins 14. The amount of such epi semiconductor material 24 formed may vary depending upon the device 10 under construction. As noted above, in some cases, a so-called “fin merge” process may be performed to form enough epi semiconductor material 24 on each of the fins of the device 10 such that they essentially “merge” together and form a substantially continuous layer of epi semiconductor material 24 across the source/drain region of the device 10. However, a “fin-merge” process is not depicted in FIG. 1D. Even if a fin-merge process is not performed, additional epi semiconductor material 24 will typically be formed on the fins 14 to increase their size so as to facilitate contact formation to the source/drain region of the device 10.

The above-described process of forming this additional epi semiconductor material 24 is not without problems. First, the epi deposition process that is performed to form the epi semiconductor material 24 is difficult to control and can lead to the formation of an unacceptable number of undesirable defects in the resulting epi semiconductor material 24. FIG. 1E is a TEM image of a plurality of fins 14 wherein the epi semiconductor material 24 was on the fins 14. As can be seen in the dashed region 25, the epi semiconductor material 24 contains a number of defects (e.g., indicated as “lines” in FIG. 1E). The presence of such defects can reduce the performance capability of the resulting device 10.

Another problem that may arise when forming the epi semiconductor material 24 in a “non-fin-merger” process flow is that, despite best efforts by everyone involved, the epi semiconductor material 24 may be grown to such an extent that the epi semiconductor material 24 is formed in areas where it should not be located and/or is formed in such quantities that the epi semiconductor material 24 on adjacent fins 14 may undesirably merge with one another. FIG. 1F is a TEM image of a plurality of fins 14 wherein the epi semiconductor material 24 was on the fins 14. In this case, the epi semiconductor material 24 formed substantially as desired on the left-most fin 14, while, in the other two cases, the epi semiconductor material 24 merged with the epi semiconductor material 24 on an adjacent fin 14. Obviously, such unanticipated merge of the epi semiconductor material 24 on the fins 14 can cause the device 10 to function at a lesser level than that anticipated by the design process. In a worst-case scenario, the epi material that is formed on, for example, an NMOS device may inadvertently merge with the epi semiconductor material 24 formed on a fin of a PMOS device (or vice-versa). In such a situation, an electrical short may be created and the device 10 may have to be scrapped.

The present disclosure is directed to various methods of forming epitaxial semiconductor material on source/drain regions of a FinFET semiconductor device and the resulting device structures that may solve or reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming epitaxial semiconductor material on source/drain regions of a FinFET semiconductor device and the resulting device structures. One illustrative device disclosed herein includes, among other things, a fin defined in a semiconductor substrate having a crystalline structure, wherein at least a sidewall of the fin is positioned substantially in a <100> crystallographic direction of the crystalline structure of the substrate, a gate structure positioned around the fin, an outermost sidewall spacer positioned adjacent opposite sides of the gate structure, and an epi semiconductor material formed around portions of the fin positioned laterally outside of the outermost sidewall spacers in the source/drain regions of the device, wherein the epi semiconductor material has a substantially uniform thickness along the sidewalls of the fin.

One illustrative method disclosed herein includes, among other things, forming a fin in a substrate such that at least a sidewall of the substrate fin is positioned substantially in a <100> crystallographic direction of the substrate, forming a gate structure around at least a portion of the fin, forming outermost sidewall spacers adjacent the gate structure and, after forming the outermost sidewall spacers, performing an epitaxial deposition process to form an epi semiconductor material around the fin in the source/drain regions of the device, wherein the epi semiconductor material positioned adjacent the sidewalls of the fin has a substantially uniform thickness.

### BRIEF DESCRIPTION OF THE DRAWINGS

The disclosure may be understood by reference to the following description taken in conjunction with the accompanying drawings, in which like reference numerals identify like elements, and in which:

FIG. 1A depicts an illustrative example of a FinFET device with various features identified for reference purposes;

FIGS. 1B-1D depict the formation of an epitaxial semiconductor on a plurality fins in the source/drain regions of an illustrative prior art FinFET device and the crystallographic orientation of the illustrative substrate;

FIGS. 1E-1F are TEM images depicting the formation of an epitaxial semiconductor on a plurality fins in the source/drain regions of an illustrative prior art FinFET device; and

FIGS. 2A-2K depict various illustrative methods of forming epitaxial semiconductor material on source/drain regions of a FinFET semiconductor device and the resulting device structures.

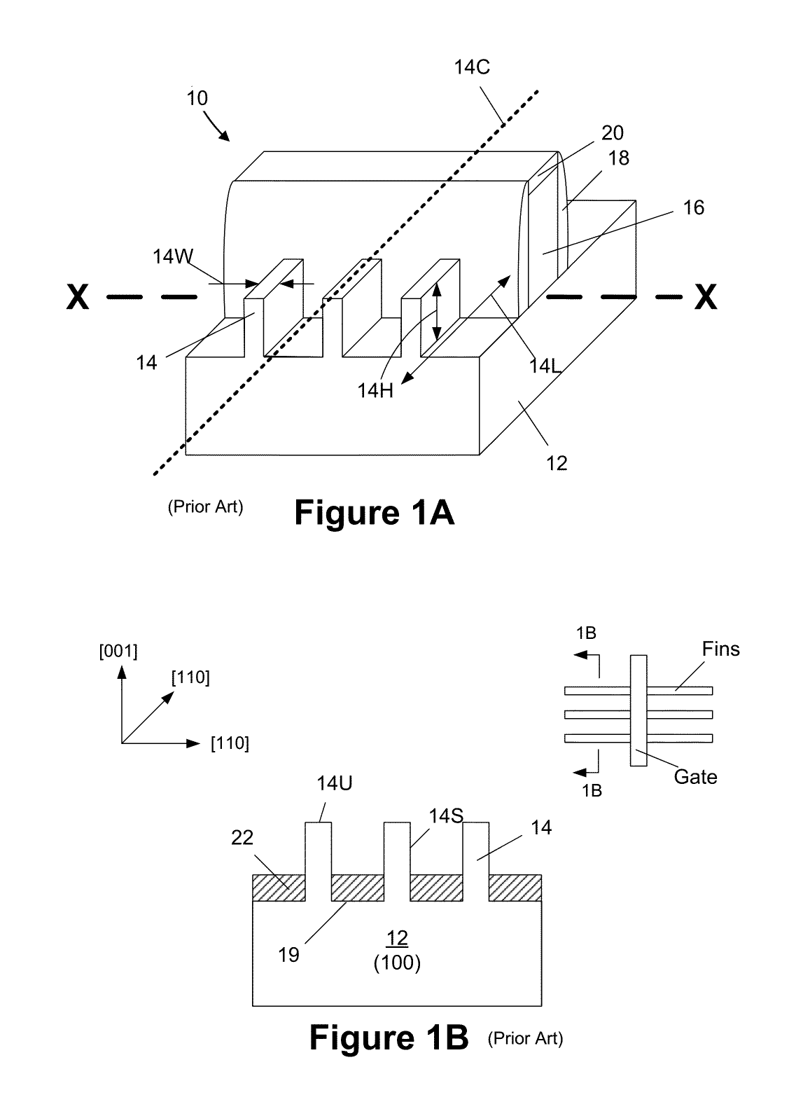

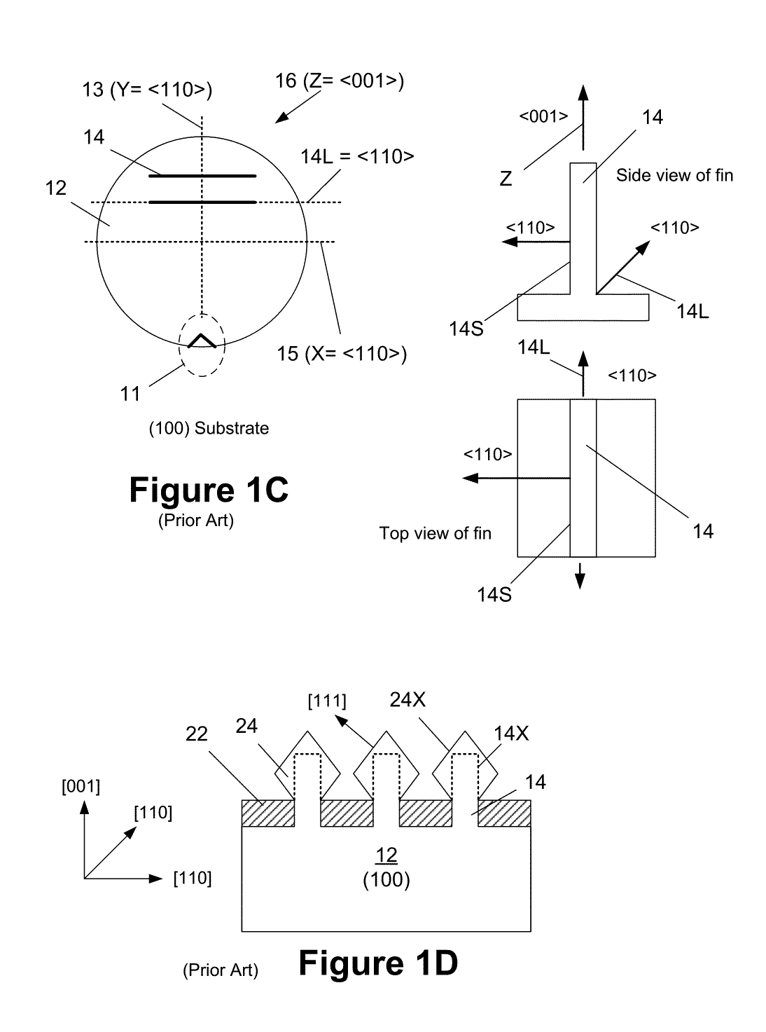

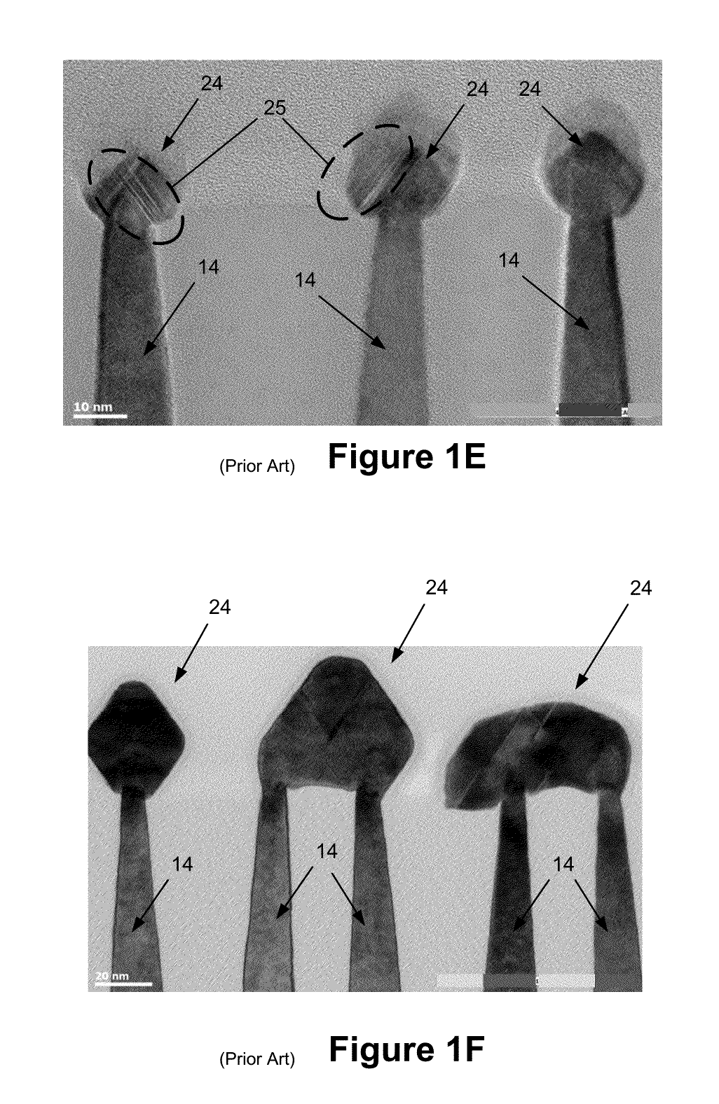

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of forming epitaxial semiconductor material on source/drain regions of a FinFET semiconductor device and the resulting device structures. The method disclosed herein may be employed in manufacturing either an N-type device or a P-type device, and the gate structure of such devices may be formed using either so-called “gate-first” or “replacement gate” (“gate-last”) techniques. As will be readily apparent to those skilled in the art upon a complete reading of the present application, the present method is applicable to a variety of devices, including, but not limited to, logic devices, memory devices, etc., and the methods disclosed herein may be employed to form N-type or P-type semiconductor devices. With reference to the attached figures, various illustrative embodiments of the methods and devices disclosed herein will now be described in more detail.

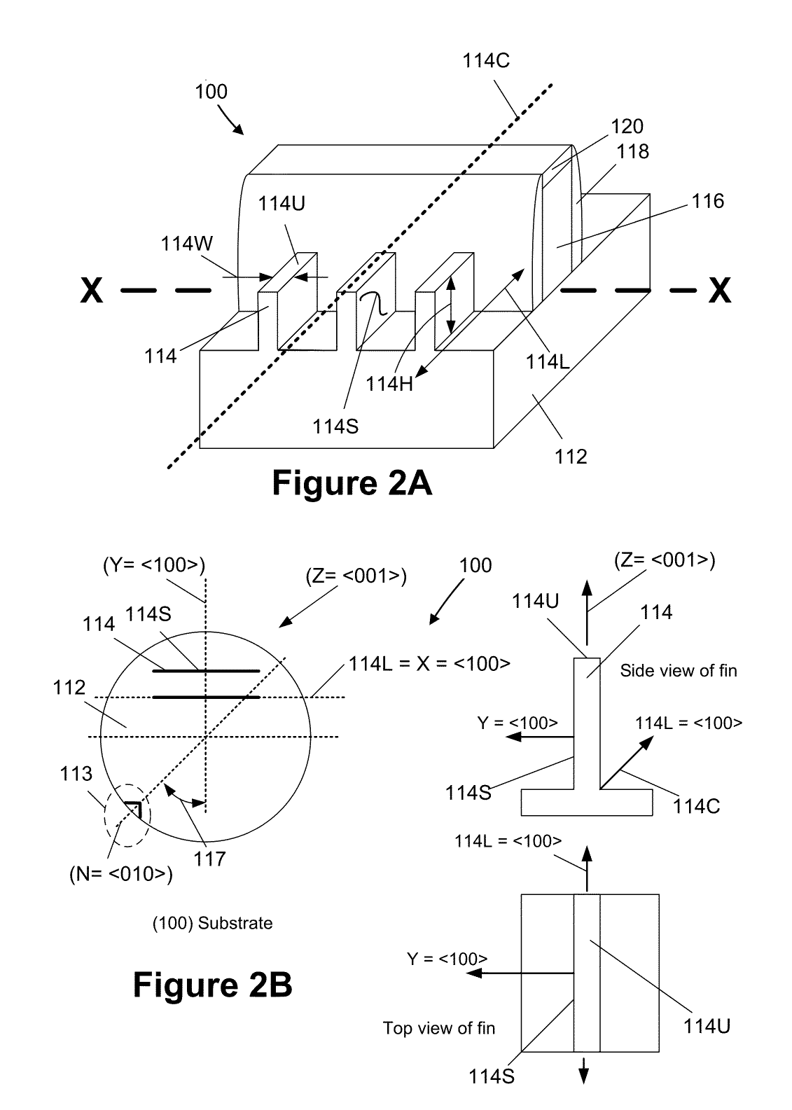

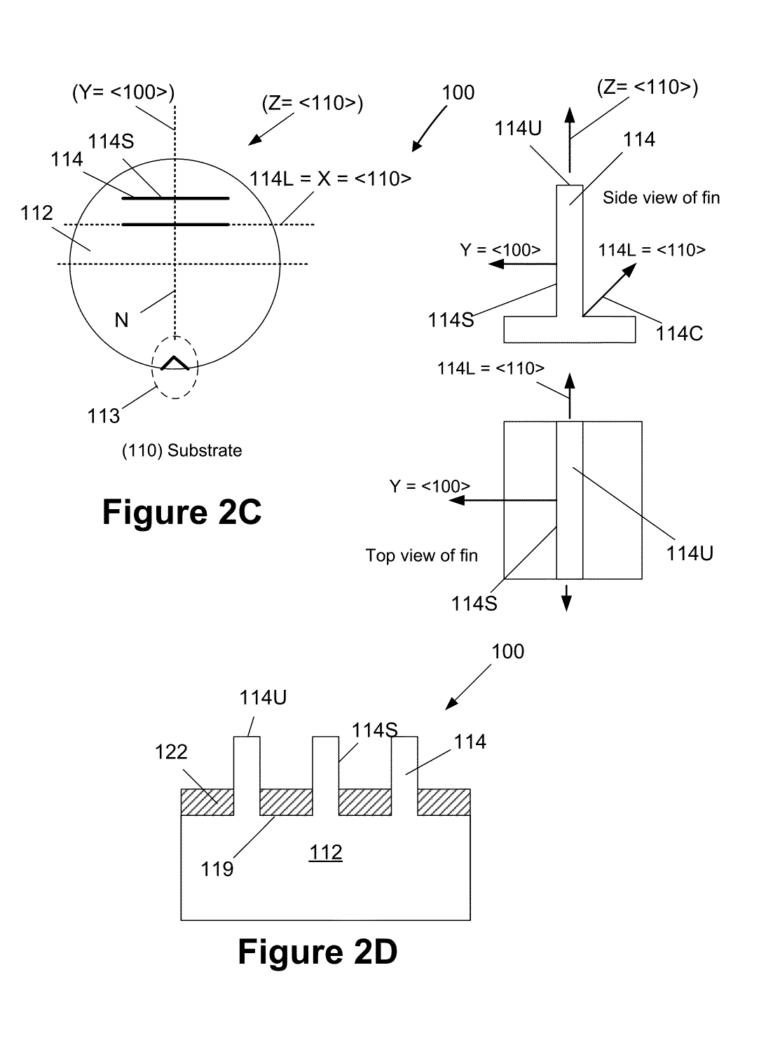

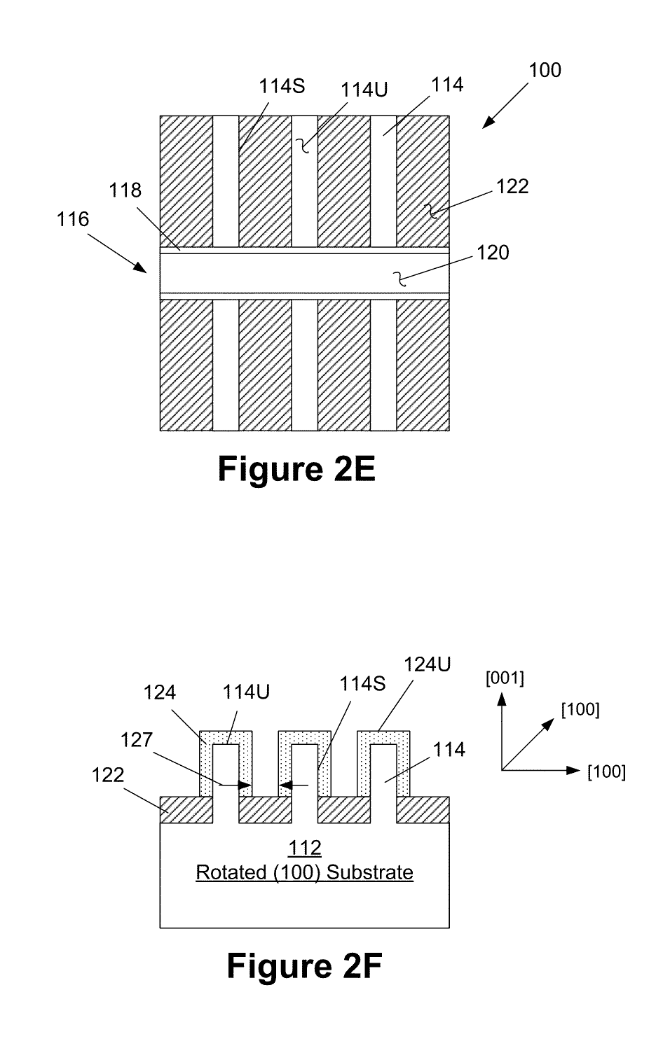

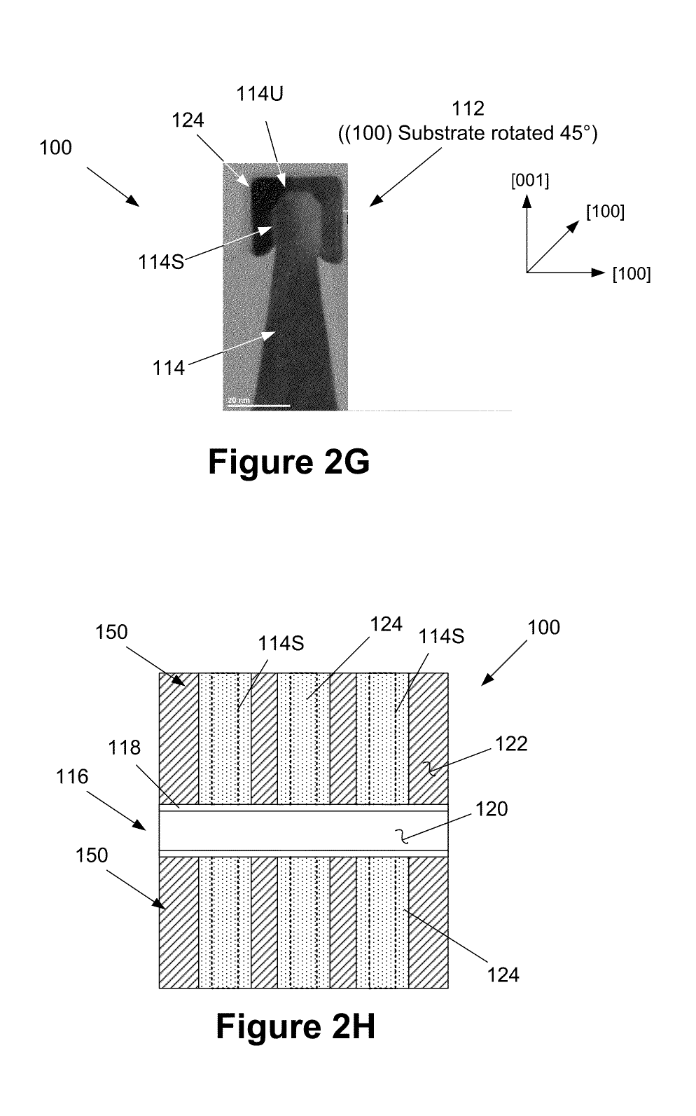

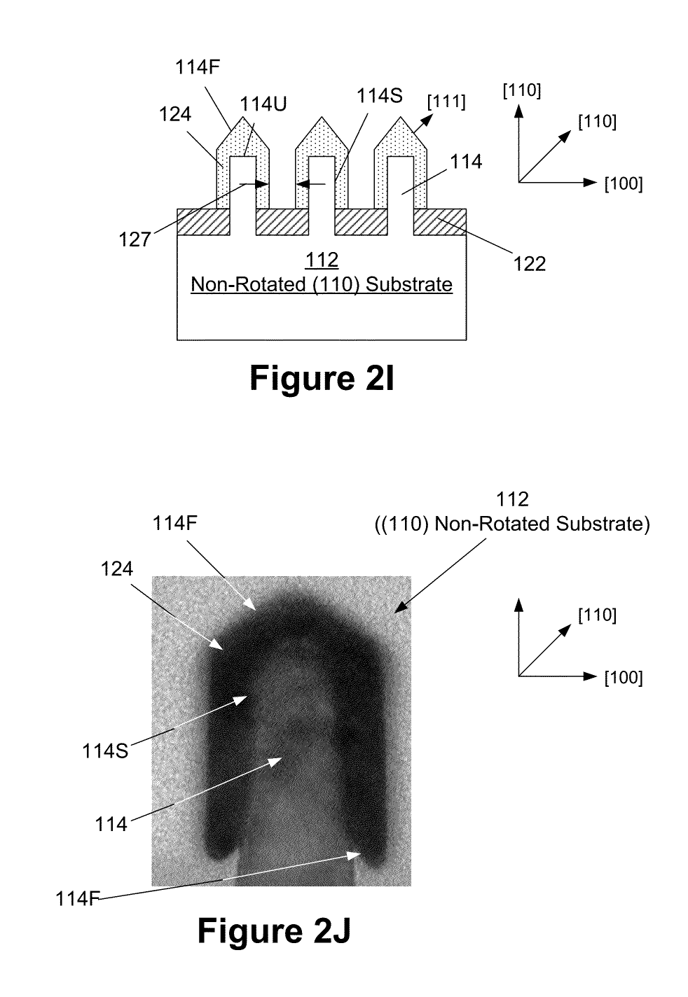

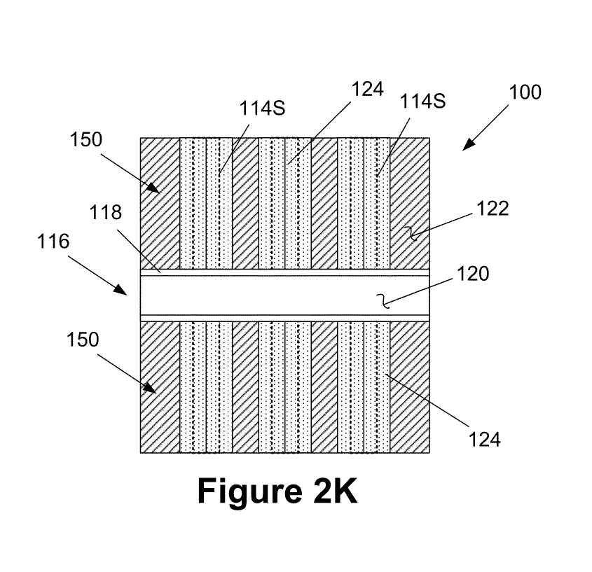

FIG. 2A is a perspective view of an illustrative FinFET semiconductor device 100 that may be formed in accordance with the methods disclosed herein. The device 100 is formed above a semiconductor substrate 112. The illustrative substrate 112 may be a bulk semiconductor substrate, or it may be the active layer of a so-called SOI (silicon-on-insulator) substrate or a so-called SGOI (silicon/germanium on insulator) substrate. Thus, the terms “substrate,” “semiconductor substrate” or “semiconducting substrate” should be understood to cover all semiconductor materials and all forms of such semiconductor materials. The device 100 may be either a P-type FinFET device or an N-type FinFET device.

With continuing reference to FIG. 2A, in this example, the FinFET device 100 includes three illustrative fins 114, a gate structure 116, outermost sidewall spacers 118 and a gate cap layer 120. The gate structure 116 is typically comprised of a layer of gate insulating material (not separately shown), e.g., a layer of high-k insulating material or silicon dioxide, and one or more conductive material layers (e.g., metal and/or polysilicon) that serve as the gate electrode for the device 100. The gate structure 116 may be formed using either “replacement gate” or “gate-first” manufacturing techniques. The fins 114 have a three-dimensional configuration: a height 114H, a width 114W and a long-axis or axial length 114L. The axial length 114L corresponds to the direction of current travel in the device 100 when it is operational. The dashed line 114C depicts the long-axis or centerline of the fins 114. The portions of the fins 114 covered by the gate structure 116 are the channel regions of the FinFET device 100. In a conventional process flow, the portions of the fins 114 that are positioned outside of the outermost spacers 118, i.e., in the source/drain regions of the device 100, may be increased in size or even merged together by performing one or more epitaxial growth processes. The process of increasing the size of or merging the fins 114 in the source/drain regions of the device 100 is typically performed to, among other things, reduce the resistance of source/drain regions and/or make it easier to establish electrical contact to the source/drain regions. In many cases, the fins 114 may be undoped or have a low dopant concentration, which tends to result in poor or less than desirable electrical contact. Even if an epi “merger” process is not performed, an epi growth process will typically be performed on the fins 114 to increase their physical size. View “X-X” in FIG. 2A depicts the locations where various cross-sectional views of the devices disclosed herein may be taken in the drawings discussed below, i.e., through what will become a source/drain region for the device 100 in a direction that is perpendicular to the long axis 114L of the fins 114 (or stated another way, in a direction that is parallel to the gate width direction of the device 100).

In general, the inventors have discovered that by orienting the sidewalls and/or long axis 114L of the fins 114 of a FinFET device 100 in a certain crystallographic orientation, the formation of epi semiconductor material around the fins 114 in the source/drain regions of the device 100 may be performed in such a manner that the resulting epi semiconductor material does not form so as to exhibit the generally diamond-shaped cross-sectional configuration of the epi semiconductor material 24 described in the background section of this application. Moreover, forming the epi semiconductor material around the fins 114 that are formed on substrates 112 oriented as described herein, better control can be achieved in forming such epi semiconductor material around the fins 114 in the source/drain regions of the device 100 with relatively few, if any, defects. Additionally, uniform epi growth yields more uniform dopant incorporation because the concentration of dopant material of even the amount (%) of germanium depends upon the crystalline orientation of the fins.

As used herein and in the claims, the term “fin” or “fins” should be understood to mean a three-dimensional structure that is comprised, in whole or part, of the material of the substrate that serves the purpose of forming a source/drain region of the FinFET device 100. That is, in one example, the fins 114 may have a substantially uniform construction, i.e., they may be formed entirely of the material of the substrate 112, e.g., silicon. Thereafter, epi semiconductor material may be formed around the source/drain portions of fins 114 having such a uniform construction. In another example, the fins 114 may have a composite structure wherein the fins are initially defined in the substrate 112, portions of the initial silicon fins are then removed and a semiconductor material (e.g., SiGe) may be formed on the remaining portion of the initial silicon fin to complete the basic composite fin structure. Thereafter, the epi semiconductor material may be formed around the source/drain portions of such a composite fin structure. Illustrative techniques for forming such a composite fin structure using various novel replacement fin techniques is disclosed in U.S. patent application Ser. No. 13/839,998, entitled “Methods of Forming Low Defect Replacement Fins for a FinFET Semiconductor Device and the Resulting Devices,” which is hereby incorporated by reference in its entirety. Such composite fin structures may also be formed using other techniques, such as aspect ratio trapping. As used herein and in the claims, the term “fin” or “fins” should be understood to cover at least both situations wherein the fins 114 have a substantially uniform construction and a composite structure. So as not to obscure the present invention, reference will be made to fins 114 having a substantially uniform composition.

FIG. 2B depicts one illustrative example disclosed herein of how the fins 114 of the FinFET device 100 may be oriented relative to the crystallographic orientation of the substrate material so as to avoid producing the generally diamond-shaped epi semiconductor material 24 described in the background section of this application. FIG. 2B depicts an illustrative substrate 112 having a (100) crystalline structure, wherein the use of “( )” denotes a specific plane. Such (100) substrates are well known in the art and are generally commercially available from a number of manufacturers. As is well known to those skilled in the art, the (100) substrate 112 is manufactured in such a manner that the crystalline planes within the substrate 112 are arranged in a certain ordered arrangement. As used herein, the “< >” designation reflects an identification of a family of equivalent directions. The plan view in FIG. 2B reflects one illustrative embodiment disclosed herein for orienting the illustrative fins 114 of the FinFET device 100 relative to various crystallographic structures of the (100) substrate 112. As is customary, the (100) substrate 112 includes a notch 113 that is aligned with the <010> crystallographic plane, i.e., the notched plane “N” of the substrate 112. In this embodiment, the (100) substrate 112 is rotated 45 degrees relative to the vertical, as indicated by the angle 117, and the fins 114 are manufactured such that the long axis 114L of the fins 114 is oriented at 45 degrees relative to the notched plane “N” of the (100) substrate 112. For example, FIG. 2B depicts a plan view of such an illustrative (100) substrate 112 with a surface normal in the (100) crystalline plane. As thus oriented, the sidewalls 114S of the fins 114 are oriented in the <100> crystallographic direction in the “Y” or vertical direction (in the plan view) and the long axis 114L of the fins 114 are oriented in the <100> crystallographic direction in the “X” or horizontal direction (in the plan view). The upper surface 114U of the fins 114 are oriented in the <001> crystallographic direction in the “Z” direction i.e., in the direction into and out of the plan view drawing in FIG. 2B. Also depicted in FIG. 2B is a cross-sectional view and a top view of an illustrative fin structure 114 showing the crystalline orientation of various aspects of the fin 114 that is formed in the (100) substrate 112 with the notch 113 rotated 45 degrees relative to the vertical. As can be seen in these views, the long axis 114L of the fin 114 is positioned in the <100> crystallographic direction of the crystalline structure of the substrate 112, while the sidewalls 114S of the fins 114 are also positioned in the <100> direction of the crystalline structure of the rotated (100) substrate 112.

FIG. 2C depicts another illustrative example disclosed herein of how the fins 114 of the FinFET device 100 may be oriented relative to the crystallographic orientation of the substrate material so as to avoid producing the generally diamond-shaped epi semiconductor material 24 described in the background section of this application. FIG. 2C depicts an illustrative substrate 112 having a (110) crystalline structure, wherein the use of “( )” denotes a specific plane. Such (110) substrates 112 are well known in the art and are generally commercially available from a number of manufacturers. As is well known to those skilled in the art, the (110) substrate 112 is manufactured in such a manner that the crystalline planes within the substrate 112 are arranged in a certain ordered arrangement. The plan view in FIG. 2C reflects one illustrative embodiment disclosed herein for orienting the illustrative fins 114 of the FinFET device 100 relative to various crystallographic structures of the (110) substrate 112. As is customary, the (110) substrate 112 includes a notch 113 that is aligned with the <100> crystallographic plane, i.e., the notched plane “N” of the substrate 112. In this embodiment, the (110) substrate 112 is not rotated relative to the vertical, and the fins 114 are manufactured such that the long axis 114L of the fins 114 is oriented perpendicular relative to the notched plane “N” of the (110) substrate 112. For example, FIG. 2C depicts a plan view of such an illustrative (110) substrate 112 with a surface normal “Z” in the (110) crystalline plane. As thus oriented, the sidewalls 114S of the fins 114 are oriented in the <100> crystallographic direction in the “Y” or vertical direction (in the plan view) and the long axis 114L of the fins 114 are oriented in the <110> crystallographic direction in the “X” or horizontal direction (in the plan view). The upper surface 114U of the fins 114 are oriented in the <110> crystallographic direction in the “Z” direction i.e., in the direction into and out of the plan view drawing in FIG. 2C. Also depicted in FIG. 2C is a cross-sectional view and a top view of an illustrative substrate fin structure 114 showing the crystalline orientation of various aspects of the fin 114 that is formed in the non-rotated (110) substrate 112. As can be seen in these views, the long axis 114L of the fin 114 is positioned in the <110> crystallographic direction of the crystalline structure of the substrate 112, while the sidewalls 114S of the fins 114 are positioned in the <100> direction of the crystalline structure of the non-rotated (110) substrate 112.

One illustrative process flow that may be employed to form the device 100 on either the rotated (100) substrate 112 or the non-rotated (110) substrate 112 will now be described with reference to the following drawings. At the point in time where the epi semiconductor material is formed around the fins 114 in the source/drain regions of the device 100, the differences that may result from using either the rotated (100) substrate 112 or the non-rotated (110) substrate 112 will be discussed. Of course, other process flows may be used to form the fins 114 of the device 100 disclosed herein. Thus, the methods and devices disclosed herein should not be considered to be limited to the illustrative process flow described herein.

At the point of fabrication depicted in FIG. 2D, one or more etching processes were performed on the substrate 112 through a patterned etch mask (not shown) to define a plurality of trenches 119 in the substrate 112. The formation of the trenches 119 results in the formation of a plurality of fins 114. Thereafter, the trenches 119 were overfilled with an insulating material 122 and a planarization process, e.g., a CMP process or an etch-back process, was performed to planarize the upper surface of the layer of insulating material 122 with the upper surface of the fins 114. Thereafter, an etch-back process is performed to recess the layer of insulating material 122 between the fins 114 and thereby expose the upper portions of the fins 114, which corresponds to the final fin height of the fins 114. As noted above, in the case of the rotated (100) substrate 112 embodiment, the long axis 114L of the fins 114 will be oriented in the <100> direction of the rotated (100) substrate 112. In the case of the non-rotated (110) substrate 112 embodiment, the long axis 114L of the fins 114 will be oriented in the <110> direction of the non-rotated (110) substrate. Additionally, in the cross-sectional views shown herein, the sidewalls 114S of the fins 114 are substantially positioned in the <100> crystallographic direction of the substrate 112 for either the rotated (100) substrate or the non-rotated (110) substrate, as shown in FIGS. 2G and 2J. The layer of insulating material 122 discussed herein may be comprised of a variety of different materials, such as, for example, silicon dioxide, silicon nitride, silicon oxynitride or any other dielectric material in common use in the semiconductor manufacturing industry, etc., or multiple layers thereof, etc., and it may be formed by performing a variety of techniques, e.g., chemical vapor deposition (CVD), etc.

The depth and width of the trenches 119 as well as the height and width of the fins 114 may vary depending upon the particular application. In one illustrative embodiment, based on current day technology, the width of the trenches 119 may range from about 10 nm to several micrometers. In some embodiments, the fins 114 may have a width within the range of about 5-30 nm. In the illustrative examples depicted in the attached figures, the trenches 119 and the fins 114 are all of a uniform size and shape. However, such uniformity in the size and shape of the trenches 119 and the fins 114 may not be required to practice at least some aspects of the inventions disclosed herein. In the example disclosed herein, the trenches 119 are depicted as having been formed by performing an anisotropic etching process that results in the trenches 119 having a schematically depicted, generally rectangular configuration with substantially vertical sidewalls. In an actual real-world device, the sidewalls of the trenches 119 may be somewhat inwardly tapered, although that configuration is not depicted in the attached drawings. In some cases, the trenches 119 may have a reentrant profile near the bottom of the trenches 119. To the extent the trenches 119 are formed by performing a wet etching process, the trenches 119 may tend to have a more rounded configuration or non-linear configuration as compared to the generally rectangular configuration of the trenches 119 that are formed by performing an anisotropic etching process. Thus, the size and configuration of the trenches 119, and the manner in which they are made, should not be considered a limitation of the present invention. For ease of disclosure, only the substantially rectangular trenches 119 and fins 114 will be depicted in subsequent drawings. In the case of fins 114 having a tapered cross-sectional configuration (not shown), the sidewalls 114S of such tapered fins may be positioned slightly out of the <100> direction noted above due to the tapered shape of the fins 114. Of course, if desired, the fins 114 may be manufactured to have more vertically oriented sidewalls or even substantially vertical sidewalls, as depicted in the attached drawings. The more vertical the sidewalls 114S of the fins 114, the more closely the sidewalls 114S will be positioned in the <100> direction of the substrate 112. Thus, when it is stated herein and in the attached claims that the long-axis 114L or centerline of the fins 114 disclosed herein are positioned in the <100> direction of the substrate 112, it is intended to cover fins 114 so oriented irrespective of their cross-sectional configuration, i.e., irrespective of whether the fins 114 are tapered or rectangular or any other shape when viewed in cross-section.

FIG. 2E is a plan view after the above-described gate structure 116 was formed on the device 100 above the fins 114 shown in FIG. 2D. The gate structure 116 is intended to be representative in nature of any gate structure that may be formed on semiconductor devices. The illustrative gate structure 116 may be formed using well-known techniques. i.e., gate-first or gate-last techniques. Also depicted in FIG. 2E are the spacers 118 and the gate cap layer 120. To the extent that any insulation material would be present above the upper surface 114U of the fins 114 at this point in fabrication, such insulation material is not depicted so as not to obscure the present invention. Of course, the materials of construction used for the gate structure 116 on a P-type FinFET device may be different than the materials used for the gate structure 116 on an N-type FinFET device. In one illustrative embodiment, the schematically depicted gate structure 116 includes an illustrative gate insulation layer (not shown) and an illustrative gate electrode (not shown). The gate insulation layer may be comprised of a variety of different materials, such as, for example, silicon dioxide, a so-called high-k (k greater than 7) insulation material (where k is the relative dielectric constant), etc. The thickness of the gate insulation layer may also vary depending upon the particular application, e.g., it may have a physical thickness of about 1-2 nm. Similarly, the gate electrode may also be of a variety of conductive materials, such as polysilicon or amorphous silicon, or it may be comprised of one or more metal layers that act as the gate electrode. As will be recognized by those skilled in the art after a complete reading of the present application, the gate structure 116 depicted in the attached drawings, i.e., the gate insulation layer and the gate electrode, are intended to be representative in nature. That is, the gate structure 116 may be comprised of a variety of different materials and they may have a variety of configurations. In one illustrative embodiment, a thermal oxidation process may be performed to form a gate insulation layer comprised of a semiconductor-based oxide material, such as germanium oxide, silicon dioxide, a high-k layer of insulating material, HfO₂, Al₂O₃, etc. Thereafter, the gate electrode material and the gate cap layer material (not shown) may be deposited above the device 100 and the layers may be patterned using known photolithographic and etching techniques. In another illustrative embodiment, a conformal CVD or ALD process may be performed to form a gate insulation layer comprised of, for example, hafnium oxide. Thereafter, one or more metal layers (that will become the gate electrode) and a gate cap layer material (not shown), e.g., silicon nitride, may be deposited above the device 100.

As shown in FIG. 2F, after the gate structure 116 is formed (either in the form of a final gate structure or as sacrificial gate structure), a subsequent process operation involves the formation of an epitaxially deposited/grown semiconductor material 124 around the fins 114 in the source/drain regions of the device 100, i.e., on the portions of the fins 114 positioned laterally outside of the spacers 118. FIG. 2F depicts epi semiconductor material 124 as it is formed around the fins 114 that is formed on the rotated (100) substrate 112. As can be seen in FIG. 2F, when the fins 114 are formed on a rotated (100) substrate 112, epi semiconductor material 124 takes on a conformal cladding or box-like configuration. Note that, in this embodiment, the epi semiconductor material 124 has a substantially uniform thickness (+/−10%) on the sidewalls 114S and the upper surface 124U of the epi semiconductor material 124 (the portion positioned above the upper surface 114U of the fins 114) is substantially planar. The thickness of the epi material 124 in the corner regions may experience somewhat more thickness variation, and it may be, on average, slightly thicker in the corner regions than on the sidewalls or above the upper surface of the fin 114. In some embodiments, the thickness of the portion of the epi semiconductor material 124 positioned above the upper surface 114U of the fins 114 may be slightly less than the thickness of the epi semiconductor material 124 positioned adjacent the sidewalls of the fins 114.

Importantly, due to the crystallographic orientation of the sidewalls 114S and the upper surface 114U, the formation of the diamond-shaped epi material 24 (as described in the background section of this application) is substantially avoided, since the sidewalls 114S ((100) orientation) and the upper surface 114U ((001) orientation) or the rotated (100) substrate are not positioned in the (110) plane as is customary when the fins 114 are fabricated on a non-rotated (100) substrate 112. As a result of the formation of the box-like epi semiconductor material 124 shown in FIG. 2F, the spacing 127 between adjacent regions of epi semiconductor material 124 is greater than the spacing between adjacent regions of the diamond-shaped epi semiconductor material 24 described in the background section of this application. Accordingly, using the methods disclosed herein, there is less chance of the problems described in the background section of this application occurring, e.g., over-growth of epi semiconductor material 24.

In one example, the epi semiconductor material 124 may be formed such that it has a desired thickness (around the perimeter of the fin 114) equal to a dimension that corresponds to about the (fin pitch−fin width)/2×0.75. The 75% factor is to allow for a sufficient process window. Of course, the absolute magnitude of the thickness may vary depending upon the device under construction. The epi semiconductor material 124 may be formed by performing a traditional epitaxial deposition/growth process. The epi semiconductor material 124 may be comprised of a variety of different materials, e.g., silicon, silicon/germanium, germanium, silicon phosphorous (SiP), silicon carbon phosphorous (SiCP), germanium tin (GeSn), Si:B, SiGe:B, SiGe:P, SiGe:As, etc.

FIG. 2G is a TEM photograph of a device 100 wherein the methods disclosed herein were employed in forming the device. In general, the device includes a fin 114 and epi semiconductor material 124 positioned around the fin 114. In the device shown in FIG. 2G, the substrate 112 is a rotated)(45° silicon (100) substrate wherein the long axis of the fin 114 (fin centerline that runs into and out of the drawing page) is positioned in the <100> direction of rotated silicon substrate 112. As noted above, in the case of the tapered fins 114, the sidewalls 114S of such tapered fins may be positioned slightly out of the <100> direction due to the tapered shape of the depicted fins. In the example depicted in FIG. 2G, the epi semiconductor material 124 was comprised of SiGeB, and the thickness of the epi semiconductor material 124 was a little over 6 nm.

FIG. 2H is a plan view of the device 100 after the above-described epi semiconductor material 124 was formed around the fins 114 of the device in the areas laterally outside of the spacers 118, i.e., in the source/drain regions 150 of the device 100. The approximate position of the sidewalls 114S of the original fins 114 is depicted in dashed lines in FIG. 2H.

FIG. 2I depicts an embodiment wherein the epi semiconductor material 124 has been formed around the fins 114 that are formed on the non-rotated (110) substrate 112. As can be seen in FIG. 2I, when the fins 114 are formed on a non-rotated (110) substrate 112, the epi semiconductor material 124 takes on a conformal cladding or box-like configuration adjacent the sidewalls 114S of the fins 114. However, since the upper surface 114U of the fin 114 depicted in FIG. 2I is positioned in the <110> crystallographic plane, the portions of the epi semiconductor material 124 formed above the upper surface 114U take on a diamond-like configuration with faceted surfaces 114F that are oriented in the [111] direction. That is, the epi semiconductor material 124 formed above the upper surface 114U of the fin 114 shown in FIG. 2I has faceted surfaces 114F that are oriented in the <111> plane, with the resulting consequence being the formation of the diamond-shaped upper portion of the epi semiconductor material 124. Importantly, due to the crystallographic orientation of the sidewalls 114S, the formation of the diamond-shaped epi material 24 (as described in the background section of this application) along the sidewalls 114S of the fins 114 is substantially avoided, since the sidewalls 114S ((100) orientation) are not positioned in the (110) plane of the substrate 112. As a result of the formation of the box-like epi semiconductor material 124 on at least the sidewalls 114S of the fins 114, as shown in FIG. 2I, the spacing 127 between adjacent regions of epi semiconductor material 124 is greater than the spacing between adjacent regions of the diamond-shaped epi semiconductor material 24 described in the background section of this application. Accordingly, using the methods disclosed herein, there is less chance of the problems described in the background section of this application occurring, e.g., over-growth of epi semiconductor material 24. In one example, the epi semiconductor material 124 shown in FIGS. 2I-2K may be formed to the same thickness, and may be comprised of the same materials as those described above in connection with the embodiment shown in FIGS. 2E-2G.

FIG. 2J is a TEM photograph of a device 100 wherein the methods disclosed herein were employed in forming the device. In general, the device includes a fin 114 and epi semiconductor material 124 positioned around the fin 114. In the device shown in FIG. 2J, the substrate 112 is a non-rotated silicon (110) substrate wherein the long axis of the fins 114 (fin centerline that runs into and out of the drawing page) is positioned in the <110> direction of non-rotated (110) silicon substrate 112. As depicted, the epi semiconductor material 124 formed above the upper surface 114U of the fin 114 shown in FIG. 2J has faceted surfaces 114F that are oriented in the <111> plane. Also note the faceted surface 114F near the bottom of the fin above the oxide material. As noted above, in the case of the tapered fins 114, the sidewalls 114S of such tapered fins may be positioned slightly out of the <100> direction due to the tapered shape of the depicted fins. In the example depicted in FIG. 2J, the epi semiconductor material 124 was comprised of SiGeB, and the thickness of the epi semiconductor material 124 was a little under 6 nm.

FIG. 2K is a plan view of the device 100 after the above-described epi semiconductor material 124 was formed around the fins 114 of the device 100 shown in FIG. 2I in the areas laterally outside of the spacers 118, i.e., in the source/drain regions 150 of the device 100. The approximate position of the sidewalls 114S of the original fins 114 is depicted in dashed lines in FIG. 2K. At the point of fabrication depicted in FIG. 2H or 2K, traditional manufacturing techniques may be performed to complete the manufacture of the device 100. For example, contacts to the source/drain regions 150 and metallization layers may then be formed above the device 100 using traditional techniques.

As between the two embodiments, the formation of the fins 114 on the non-rotated (110) substrate 112 as described above may provide some advantages as the current transport direction of the device 100 in that embodiment is in the (110) crystallographic plane, which may facilitate current transport in some applications.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A device, comprising:
a fin defined in a semiconductor substrate having a crystalline structure, wherein at least a sidewall of said fin is positioned substantially in a <100> crystallographic direction of said crystalline structure of said substrate;
a gate structure positioned around said fin;
an outermost sidewall spacer positioned adjacent opposite sides of said gate structure; and
an epi semiconductor material formed around portions of said fin positioned laterally outside of said outermost sidewall spacers in source/drain regions of said device, wherein said epi semiconductor material has a substantially uniform thickness along said sidewalls of said fin.

2. The device of claim 1, wherein said substrate is a (100) substrate, said substrate fin has a long axis, wherein said long axis of said fin is positioned in a <100> crystallographic direction of said (100) substrate.

3. The device of claim 2, wherein said epi semiconductor material is positioned around an upper surface of said fin and wherein an upper surface of said epi semiconductor material that is positioned above said upper surface of said fin has a substantially planar surface.

4. The device of claim 3, wherein an upper surface of said fin is positioned in a <001> crystallographic direction of said (100) substrate.

5. The device of claim 1, wherein said substrate is a (110) substrate and said substrate fin has a long axis, wherein said long axis of said substrate fin is positioned in a <110> crystallographic direction of said crystalline structure of said (110) substrate.

6. The device of claim 5, wherein said epi semiconductor material is positioned around an upper surface of said fin and wherein an upper surface of said epi semiconductor material that is positioned above said upper surface of said fin has a plurality of faceted surfaces.

7. The device of claim 6, wherein an upper surface of said fin is positioned in a <110> crystallographic direction of said (110) substrate.

8. The device of claim 1, wherein said epi semiconductor material is comprised of one of silicon, Si:B, SiGe:B, GeSn, silicon/germanium, SiP, SiCP, SiGe:P or SiGe:As.

9. The device of claim 1, wherein said substrate is comprised of silicon.

10. The device of claim 1, wherein, other than said epi semiconductor material, said fin is comprised of at least one semiconductor material other than said semiconductor material of said substrate.

11. The device of claim 1, wherein, other than said epi semiconductor material, said fin is comprised of only said semiconductor material of said substrate.

12. A method of forming a FinFET device, comprising:
forming a fin in a substrate such that at least a sidewall of said substrate fin is positioned substantially in a <100> crystallographic direction of said substrate;
forming a gate structure around at least a portion of said fin;
forming outermost sidewall spacers adjacent said gate structure; and
after forming said outermost sidewall spacers, performing an epitaxial deposition process to form an epi semiconductor material around said fin in source/drain regions of said device, wherein said epi semiconductor material positioned adjacent said sidewalls of said fin has a substantially uniform thickness.

13. The method of claim 12, wherein said substrate is a (100) substrate and wherein forming said fin in said substrate comprises forming said fin such that a long axis of said fin is positioned in a <100> crystallographic direction of said (100) substrate.

14. The method of claim 13, wherein forming said epi semiconductor material comprises forming said epi semiconductor material above an upper surface of said fin such that a portion of said epi semiconductor material positioned above said upper surface of said fin has a substantially planar upper surface.

15. The method of claim 14, wherein forming said fin comprises forming said fin such that said upper surface of said fin is positioned in a <001> crystallographic direction of said (100) substrate.

16. The method of claim 12, wherein said substrate is a (110) substrate and wherein forming said fin in said substrate comprises forming said fin such that a long axis of said fin is positioned in a <110> crystallographic direction of said (110) substrate.

17. The method of claim 16, wherein forming said epi semiconductor material comprises forming said epi semiconductor material above an upper surface of said fin such that a portion of said epi semiconductor material positioned above said upper surface of said fin has a plurality of faceted surfaces.

18. The method of claim 17, wherein forming said fin comprises forming said fin such that said upper surface of said fin is positioned in a <110> crystallographic direction of said (110) substrate.
